(19) United States
(12) Patent Application Publication
(10) Pub. No.: US 2026/0262335 A1
(43) Pub. Date: Sep. 3, 2026

(54) LIGHT-EMITTING DIODE

(71) Applicant: BOE HC SEMITEK (SUZHOU) CO., LTD., Suzhou (CN)

(72) Inventors: Shijun WANG, Suzhou (CN); Tong LI, Suzhou (CN); Mu SONG, Suzhou (CN); Zhenyuan XING, Suzhou (CN)

(21) Appl. No.: 19/558,435

(22) Filed: Mar. 5, 2026

Related U.S. Application Data
(63) Continuation-in-part of application No. PCT/CN2024/100151, filed on Jun. 19, 2024.

(30) Foreign Application Priority Data
Sep. 6, 2023 (CN) 202311146567.5

(51) Int. Cl. H10H 20/812; H10H 20/815; H10H 20/824

(52) U.S. Cl. CPC H10H 20/812; H10H 20/815; H10H 20/8242

(57) ABSTRACT

A light-emitting diode including a first light-emitting unit, a first buffer layer, a first tunneling junction, a second buffer layer, and a second light-emitting unit stacked in sequence. The first light-emitting unit includes a first semiconductor layer having a first conductivity type. The second light-emitting unit includes a second semiconductor layer having a second conductivity type. The first tunneling junction includes a third semiconductor layer having the first conductivity type and a fourth semiconductor layer having the second conductivity type. The first conductivity type is different from the second conductivity type. A bandgap width of the first buffer layer is between a bandgap width of the first semiconductor layer and a bandgap width of the third semiconductor layer, and a bandgap width of the second buffer layer is between a bandgap width of the fourth semiconductor layer and a bandgap width of the second semiconductor layer.

### CROSS-REFERENCE TO RELATED APPLICATION

This application is a continuation-in-part of International Patent Application No. PCT/CN2024/100151 with an international filing date of Jun. 19, 2024, designating the United States, now pending, further claims foreign priority benefits to Chinese Patent Application No. 202311146567.5 filed Sep. 6, 2023. The contents of all of the aforementioned applications, including any intervening amendments thereto, are incorporated herein by reference. Inquiries from the public to applicants or assignees concerning this document or the related applications should be directed to: Matthias Scholl P.C., Attn.: Dr. Matthias Scholl Esq., 245 First Street, 18th Floor, Cambridge, MA 02142.

### BACKGROUND

The disclosure relates to the field of semiconductor technology, and in particular, to a light-emitting diode.

Red micro light-emitting diodes (LEDs) have low luminous efficiency under small currents. Connecting multiple PN junctions in series by epitaxially growing a tunneling junction can address the luminous efficiency issue under small currents.

However, connecting multiple PN junctions via a tunneling junction causes a significant increase in the LED voltage, thereby limiting the improvement in luminous efficiency.

### SUMMARY

Embodiments of the disclosure provide a light-emitting diode. The technical solution is as follows:

In a first aspect, an embodiment of the disclosure provides a light-emitting diode comprises a first light-emitting unit, a first buffer layer, a first tunneling junction, a second buffer layer, and a second light-emitting unit stacked in sequence. The first light-emitting unit comprises a first semiconductor layer having a first conductivity type. The second light-emitting unit comprises a second semiconductor layer having a second conductivity type. The first tunneling junction comprises a third semiconductor layer having the first conductivity type and a fourth semiconductor layer having the second conductivity type. The first conductivity type is different from the second conductivity type. A bandgap width of the first buffer layer is between a bandgap width of the first semiconductor layer and a bandgap width of the third semiconductor layer, and a bandgap width of the second buffer layer is between a bandgap width of the fourth semiconductor layer and a bandgap width of the second semiconductor layer.

Optionally, the first semiconductor layer is a first P-type AlInP confinement layer, the first buffer layer is a first hole buffer layer, the second buffer layer is a first electron buffer layer, the second semiconductor layer is a second N-type AlInP confinement layer, the third semiconductor layer is a first P-type AlGaAs layer, and the fourth semiconductor layer is a first N-type GaAs layer.

Optionally, the first buffer layer is a P-type doped (Al_{y}Ga_{1-y})_{0.5}In_{0.5}P layer, and y ranges from 0.15 to 1.

Optionally, a value of y gradually decreases in a direction from the first semiconductor layer to the first tunneling junction, wherein a maximum value of y is 1, and a minimum value of y ranges from 0.15 to 0.3.

Optionally, a doping concentration of the first buffer layer ranges from 1.5E18 to 2.5E18 cm⁻³.

Optionally, a thickness of the first buffer layer ranges from 20 to 100 nm.

Optionally, the second buffer layer is an N-type doped (Al_{z}Ga_{1-z})_{0.5}In_{0.5}P layer, and z ranges from 0.15 to 1.

Optionally, a value of z gradually increases in a direction from the first tunneling junction to the second semiconductor layer, wherein a maximum value of z is 1, and a minimum value of z ranges from 0.15 to 0.3.

Optionally, a doping concentration of the second buffer layer ranges from 2E18 to 3E18 cm⁻³.

Optionally, a thickness of the second buffer layer ranges from 20 to 100 nm.

Optionally, the light-emitting diode further comprises a third buffer layer, a second tunneling junction, a fourth buffer layer, and a third light-emitting unit stacked in sequence on the second light-emitting unit. The second light-emitting unit further comprises a fifth semiconductor layer having the first conductivity type. The third light-emitting unit comprises a sixth semiconductor layer having the second conductivity type. The second tunneling junction comprises a seventh semiconductor layer having the first conductivity type and an eighth semiconductor layer having the second conductivity type. A bandgap width of the third buffer layer is between a bandgap width of the fifth semiconductor layer and a bandgap width of the seventh semiconductor layer, and a bandgap width of the fourth buffer layer is between a bandgap width of the eighth semiconductor layer and a bandgap width of the sixth semiconductor layer.

### BRIEF DESCRIPTION OF THE DRAWINGS

FIG. 1 is a schematic structural diagram of a light-emitting diode according to an embodiment of the disclosure;

FIG. 2 is a schematic structural diagram of a light-emitting diode according to another embodiment of the disclosure;

FIG. 3 is a schematic structural diagram of another light-emitting diode according to an embodiment of the disclosure;

FIG. 4 is a schematic structural diagram of another light-emitting diode according to another embodiment of the disclosure; and

FIG. 5 is a flowchart of a method for manufacturing a light-emitting diode according to an embodiment of the disclosure.

Reference numerals in the drawings:

10—First light-emitting unit; 20—First buffer layer; 30—First tunneling junction; 40—Second buffer layer; 50—Second light-emitting unit; 60—Third buffer layer; 70—Second tunneling junction; 80—Fourth buffer layer; 90—Third light-emitting unit; 101—GaAs substrate; 102—N-type GaAs buffer layer; 103—N-type GaInP etch stop layer; 104—N-type GaAs ohmic contact layer; 105—N-type current spreading layer; 106—First N-type AlInP confinement layer; 107—First active layer; 108—First P-type AlInP confinement layer; 109—First hole buffer layer; 111—First electron buffer layer; 112—Second N-type AlInP confinement layer; 113—Second active layer; 114—Second P-type AlInP confinement layer; 115—P-type current spreading layer; 116—Second hole buffer layer; 118—Second electron buffer layer; 119—Third N-type AlInP confinement layer; 120—Third active layer; 121—Third P-type AlInP confinement layer.

### DETAILED DESCRIPTION

To make the objectives, technical solutions, and advantages of the disclosure clearer, the embodiments of the disclosure will be described in further detail below with reference to the accompanying drawings.

In the related art, multiple PN junctions are connected via tunneling junctions. The tunneling junction comprises a P-type AlGaAs layer and an N-type GaAs layer. Electrons can easily tunnel within the tunneling junction. The tunneling junction is flanked by a P-type AlInP confinement layer and an N-type AlInP confinement layer. The P-type AlInP confinement layer is adjacent to the P-type AlGaAs layer, and the N-type AlInP confinement layer is adjacent to the N-type GaAs layer.

There is a large energy band difference between the P-type AlInP confinement layer (bandgap width of 2.45 eV) and the P-type AlGaAs layer (bandgap width of 1.4 to 1.9 eV), and there is a large energy band difference between the N-type GaAs layer (bandgap width of 1.4 eV) and the N-type AlInP confinement layer (bandgap width of 2.45 eV). Electrons cannot tunnel well at these two interfaces, leading to high voltage and low luminous efficiency, failing to achieve the desired effect.

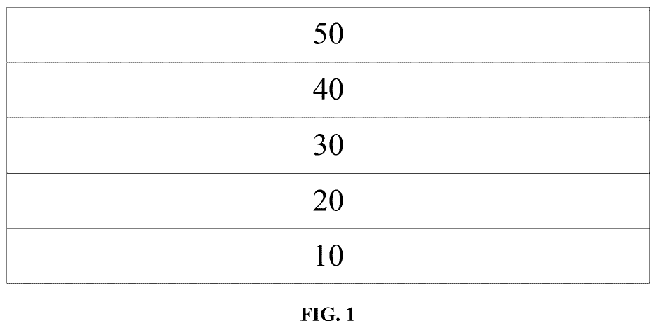

FIG. 1 is a schematic structural diagram of a light-emitting diode provided by an embodiment according to the disclosure. Referring to FIG. 1, the light-emitting diode comprises a first light-emitting unit 10, a first buffer layer 20, a first tunneling junction 30, a second buffer layer 40, and a second light-emitting unit 50 stacked in sequence.

The first light-emitting unit 10 comprises a first semiconductor layer having a first conductivity type, the second light-emitting unit 50 comprises a second semiconductor layer having a second conductivity type, and the first tunneling junction 30 comprises a third semiconductor layer having the first conductivity type and a fourth semiconductor layer having the second conductivity type. The first conductivity type is different from the second conductivity type.

A bandgap width of the first buffer layer 20 is between a bandgap width of the first semiconductor layer and a bandgap width of the third semiconductor layer, and a bandgap width of the second buffer layer 40 is between a bandgap width of the fourth semiconductor layer and a bandgap width of the second semiconductor layer.

In the embodiment of the disclosure, the first buffer layer with a moderate bandgap width is inserted between the first semiconductor layer and the third semiconductor layer, which reduces the energy band difference at the interlayer interface, allowing electrons to tunnel well across the interface. Similarly, the second buffer layer with a moderate bandgap width is inserted between the fourth semiconductor layer and the second semiconductor layer, which reduces the energy band difference at the interlayer interface, allowing electrons to tunnel well across the interface. In summary, adding the first buffer layer and the second buffer layer facilitates electron tunneling, achieving the purpose of reducing voltage and improving the luminous efficiency of the light-emitting diode.

In an example of the embodiment of the disclosure, the first conductivity type refers to a P-type semiconductor type, and the second conductivity type refers to an N-type semiconductor type. The embodiment of the disclosure introduces the structure of the light-emitting diode by taking this classification as an example.

Exemplarily, the first semiconductor layer is a first P-type AlInP confinement layer.

Optionally, the first light-emitting unit 10 further comprises a first N-type AlInP confinement layer and a first active layer.

Exemplarily, the first buffer layer 20 is a first hole buffer layer.

Exemplarily, the second buffer layer 40 is a first electron buffer layer.

Exemplarily, the second semiconductor layer is a second N-type AlInP confinement layer.

Optionally, the second light-emitting unit 50 further comprises a second active layer and a second P-type AlInP confinement layer.

Exemplarily, the third semiconductor layer is a first P-type AlGaAs layer; the fourth semiconductor layer is a first N-type GaAs layer.

In other examples of the embodiment of the disclosure, the first conductivity type refers to an N-type semiconductor type, and the second conductivity type refers to a P-type semiconductor type.

Optionally, the light-emitting diode further comprises a substrate, and a buffer layer, an etch stop layer, an ohmic contact layer, an N-type current spreading layer, etc. located between the substrate and the first light-emitting unit 10.

Optionally, the light-emitting diode further comprises a P-type current spreading layer located on the second light-emitting unit 50.

Exemplarily, the light-emitting diode provided by the embodiments of the disclosure may be a red light-emitting diode.

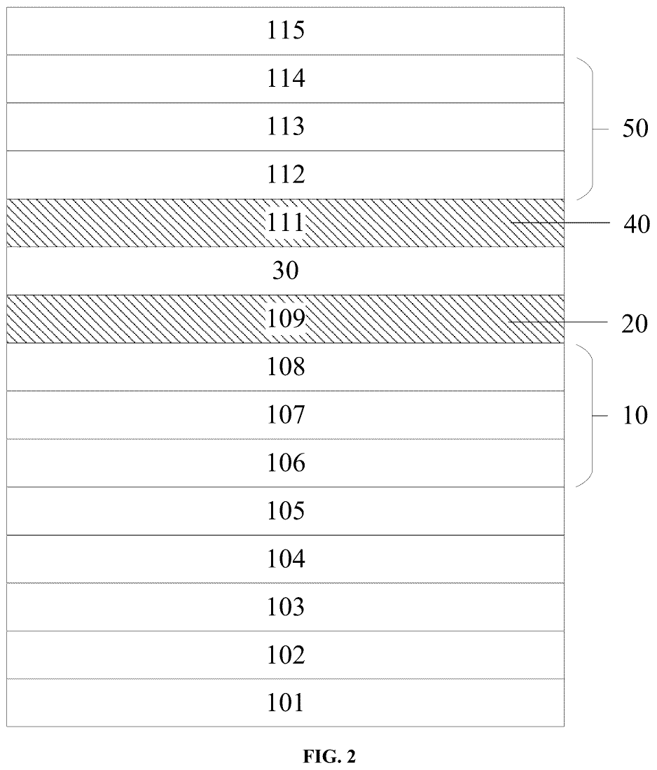

FIG. 2 is a schematic structural diagram of a light-emitting diode provided by an embodiment according to the disclosure. Compared with FIG. 1, the detailed structure of each film layer is further refined. Referring to FIG. 2, the light-emitting diode comprises a GaAs substrate 101, an N-type GaAs buffer layer 102, an N-type GaInP etch stop layer 103, an N-type GaAs ohmic contact layer 104, an N-type current spreading layer 105, a first N-type AlInP confinement layer 106, a first active layer 107, a first P-type AlInP confinement layer 108, a first hole buffer layer 109, a first tunneling junction 30, a first electron buffer layer 111, a second N-type AlInP confinement layer 112, a second active layer 113, a second P-type AlInP confinement layer 114, and a P-type current spreading layer 115.

The first N-type AlInP confinement layer 106, the first active layer 107, and the first P-type AlInP confinement layer 108 constitute the first light-emitting unit 10. The first hole buffer layer 109 is the first buffer layer 20. The first electron buffer layer 111 is the second bu20. The second N-type AlInP confinement layer 112, the second active layer 113, and the second P-type AlInP confinement layer 114 constitute the second light-emitting unit 50.

The N-type GaAs buffer layer 102, the N-type GaInP etch stop layer 103, the N-type GaAs ohmic contact layer 104, the N-type current spreading layer 105, the first N-type AlInP confinement layer 106, the first active layer 107, the first P-type AlInP confinement layer 108, the first hole buffer layer 109, the first tunneling junction 30, the first electron buffer layer 111, the second N-type AlInP confinement layer 112, the second active layer 113, the second P-type AlInP confinement layer 114, and the P-type current spreading layer 115 are stacked in sequence on the GaAs substrate 101.

The first tunneling junction 30 comprises a first P-type AlGaAs layer and a first N-type GaAs layer stacked in sequence. The bandgap width of the first hole buffer layer 109 is between the bandgap width of the first P-type AlInP confinement layer 108 and the bandgap width of the first P-type AlGaAs layer. The bandgap width of the first electron buffer layer 111 is between the bandgap width of the second N-type AlInP confinement layer 112 and the bandgap width of the first N-type GaAs layer.

In the embodiment of the disclosure, the first hole buffer layer with a moderate bandgap width is inserted between the first P-type AlInP confinement layer 108 and the first P-type AlGaAs layer, which reduces the energy band difference at the interlayer interface, allowing electrons to tunnel well across the interface. Similarly, the first electron buffer layer with a moderate bandgap width is inserted between the second N-type AlInP confinement layer 112 and the first N-type GaAs layer, which reduces the energy band difference at the interlayer interface, allowing electrons to tunnel well across the interface. In summary, adding the hole and electron buffer layers facilitates electron tunneling, achieving the purpose of reducing voltage and improving the luminous efficiency of the light-emitting diode.

Exemplarily, a thickness of the N-type GaAs buffer layer 102 is 150 to 300 nm, e.g., 200 nm. The dopant for the N-type GaAs buffer layer 102 is Si₂H₆. A doping concentration of the N-type GaAs buffer layer 102 is 1E18 to 2E18 cm⁻³, e.g., 1.5E18 cm⁻³.

Exemplarily, a thickness of the N-type GaInP etch stop layer 103 is 200 to 300 nm, e.g., 250 nm. The dopant for the N-type GaInP etch stop layer 103 is Si₂H₆. A doping concentration of the N-type GaInP etch stop layer 103 is 2E18 to 6E18 cm⁻³, e.g., 4E18 cm⁻³.

Exemplarily, a thickness of the N-type GaAs ohmic contact layer 104 is 30 to 60 nm, e.g., 45 nm. The dopant for the N-type GaAs ohmic contact layer 104 is Si₂H₆. A doping concentration of the N-type GaAs ohmic contact layer 104 is 4E18 to 6E18 cm⁻³, e.g., 5E18 cm⁻³.

Exemplarily, the N-type current spreading layer 105 is an N-type (AlₓGa₁₋ₓ)_{0.5}In_{0.5}P layer, where 0.3≤x≤1. A thickness of the N-type current spreading layer 105 is 0.8 to 1.2 μm, e.g., 1 μm. The dopant for the N-type current spreading layer 105 is Si₂H₆. A doping concentration of the N-type current spreading layer 105 is 1E18 to 4E18 cm⁻³, e.g., 2.5E18 cm⁻³.

Exemplarily, a thickness of the first N-type AlInP confinement layer 106 is 200 to 300 nm, e.g., 250 nm. The dopant for the first N-type AlInP confinement layer 106 is Si₂H₆. A doping concentration of the first N-type AlInP confinement layer 106 is 1E18 to 2E18 cm⁻³, for example, 1.5E18 cm⁻³.

Exemplarily, the first active layer 107 is a multi-quantum well layer. A thickness of a quantum well in the multi-quantum well layer is 3 to 5 nm, e.g., 4 nm; a thickness of a quantum barrier in the multi-quantum well layer is 5 to 10 nm, e.g., 8 nm. The number of periods of the multi-quantum well layer is 2 to 7, e.g., 5.

Exemplarily, a thickness of the first P-type AlInP confinement layer 108 is 200 to 300 nm, e.g., 250 nm. The dopant for the first P-type AlInP confinement layer 108 is Cp₂Mg. A doping concentration of the first P-type AlInP confinement layer 108 is 1E18 to 1.5E18 cm⁻³, e.g., 1.25E18 cm⁻³.

In the embodiment of the disclosure, the first hole buffer layer 109 is a P-type doped (Al_{y}Ga_{1-y})_{0.5}In_{0.5}P layer, and y ranges from 0.15 to 1, for example, 0.5. The dopant for the P-type doped (Al_{y}Ga_{1-y})_{0.5}In_{0.5}P layer is Cp₂Mg.

Here, the value of y represents the average Al content in the entire (Al_{y}Ga_{1-y})_{0.5}In_{0.5}P layer.

The bandgap width of P-type doped (Al_{y}Ga_{1-y})_{0.5}In_{0.5}P is 2.0 to 2.1 eV, the bandgap width of the first P-type AlInP confinement layer is 2.45 eV, and the bandgap width of the first P-type AlGaAs layer is 1.4 to 1.9 eV. It can be seen that using the above material as the first hole buffer layer can ensure that the bandgap width of the first hole buffer layer is between the bandgap widths of the first P-type AlInP confinement layer and the first P-type AlGaAs layer.

In one example, the value of y gradually decreases in a direction from the first P-type AlInP confinement layer to the first tunneling junction, the maximum value of y is 1, and the minimum value of y is 0.15 to 0.3, for example, 0.2.

In this implementation, the value of y gradually decreases in the direction from the first P-type AlInP confinement layer to the first tunneling junction, so that the bandgap width of the first hole buffer layer gradually decreases in the direction from the first P-type AlInP confinement layer to the first tunneling junction, making the energy band differences at the interfaces between the first hole buffer layer and the first P-type AlInP confinement layer and between the first hole buffer layer and the first P-type AlGaAs layer relatively small.

In other examples, the value of y may be constant or vary in other ways.

Exemplarily, a doping concentration of the first hole buffer layer is 1.5E18 to 2.5E18 cm⁻³, e.g., 2E18 cm⁻³.

In this implementation, if the doping concentration of the first hole buffer layer is too low, the voltage will be relatively high; if the doping concentration is too high, this means more impurities, which will absorb photons and lead to decreased luminous efficiency. Therefore, an appropriate doping concentration is selected to ensure voltage and luminous efficiency.

Exemplarily, a thickness of the first hole buffer layer is 20 to 100 nm, e.g., 60 nm.

In this implementation, because the hole buffer layer uses AlGaInP with a low bandgap width, if the thickness is too large, it will absorb more photons and cause a decrease in luminous efficiency; if the thickness is too small, it will not serve the hole buffering function, leading to high voltage.

Exemplarily, the first P-type AlGaAs layer in the first tunneling junction 30 is a P-type AlₐGa₁₋ₐAs layer, where 0≤a≤0.3. A thickness of the first P-type AlGaAs layer is 10 to 40 nm, e.g., 25 nm. The dopant for the first P-type AlGaAs layer is CBr₄ or CCl₄. A doping concentration of the first P-type AlGaAs layer is 0.5E20 to 2E20 cm⁻³, for example, 1E20 cm⁻³.

A thickness of the first N-type GaAs layer in the first tunneling junction 30 is 10 to 40 nm, e.g., 25 nm. The dopant for the first N-type GaAs layer is Si₂H₆ or diethyl telluride. A doping concentration of the first N-type GaAs layer is 0.8E19 to 3E19 cm⁻³, for example, 2E19 cm⁻³.

In the embodiment of the disclosure, the first electron buffer layer 111 is an N-type doped (Al_{z}Ga_{1-z})_{0.5}In_{0.5}P layer, and z ranges from 0.15 to 1, for example, 0.5. The dopant for the first electron buffer layer is Si₂H₆.

Here, the value of z represents the average Al content in the entire (Al_{z}Ga_{1-z})_{0.5}In_{0.5}P layer.

The bandgap width of the first N-type GaAs layer is 1.4 eV, and the bandgap width of the second N-type AlInP confinement layer is 2.45 eV. Using the above material as the first electron buffer layer can ensure that the bandgap width of the first electron buffer layer is between the bandgap widths of the second N-type AlInP confinement layer and the first N-type GaAs layer.

In one example, the value of z gradually increases in a direction from the first tunneling junction to the second N-type AlInP confinement layer, the maximum value of z is 1, and the minimum value of z is 0.15 to 0.3, e.g., 0.2.

In this implementation, the value of z gradually increases in the direction from the first tunneling junction to the second N-type AlInP confinement layer, so that the bandgap width of the first electron buffer layer gradually increases in the direction from the first tunneling junction to the second N-type AlInP confinement layer, making the energy band differences at the interfaces between the first electron buffer layer and the first N-type GaAs layer and between the first electron buffer layer and the second N-type AlInP confinement layer relatively small.

In other examples, the value of z may be constant or vary in other ways.

Exemplarily, a doping concentration of the first electron buffer layer is 2E18 to 3E18 cm⁻³, for example, 2.5E18 cm⁻³.

Exemplarily, a thickness of the first electron buffer layer is 20 to 100 nm, e.g., 60 nm.

Exemplarily, a thickness of the second N-type AlInP confinement layer 112 is 200 to 300 nm, e.g., 250 nm. The dopant for the second N-type AlInP confinement layer 112 is Si₂H₆. A doping concentration of the second N-type AlInP confinement layer 112 is 1E18 to 2E18 cm⁻³, e.g., 1.5E18 cm⁻³.

Exemplarily, the second active layer 113 is a multi-quantum well layer. A thickness of a quantum well in the multi-quantum well layer is 3 to 5 nm, e.g., 4 nm; a thickness of a quantum barrier in the multi-quantum well layer is 5 to 10 nm, e.g.,, 8 nm. The number of periods of the multi-quantum well layer is 2 to 7, e.g., 5.

Exemplarily, a thickness of the second P-type AlInP confinement layer 114 is 200 to 300 nm, e.g., 250 nm. The dopant for the second P-type AlInP confinement layer 114 is Cp₂Mg. A doping concentration of the second P-type AlInP confinement layer 114 is 1E18 to 1.5E18 cm⁻³, e.g., 1.25E18 cm⁻³.

Exemplarily, the P-type current spreading layer 115 is a P-type GaP layer. A thickness of the P-type current spreading layer 115 is 4 to 8 μm, e.g., 6 μm. The dopant for the P-type current spreading layer 115 is Cp₂Mg. A doping concentration of the P-type current spreading layer 115 is 1E18 to 8E18 cm⁻³, e.g., 5E18 cm⁻³.

Another light-emitting diode is provided according to another embodiment of the disclosure, which may further comprise more tunneling junctions and PN junctions.

For example, the light-emitting diode comprises 3 or more PN junctions, and a hole buffer layer, a tunneling junction, and an electron buffer layer are provided between adjacent PN junctions. The PN junction comprises an N-type confinement layer, an active layer, and a P-type confinement layer.

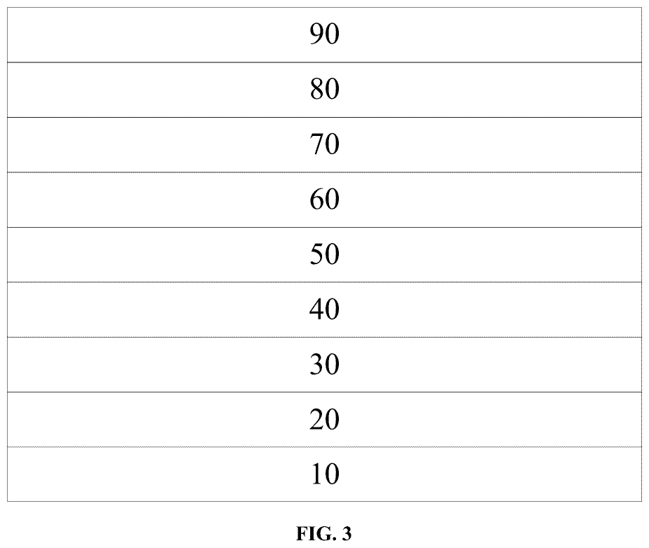

FIG. 3 is a schematic structural diagram of a light-emitting diode according to an embodiment of the disclosure. Compared with FIG. 1, this light-emitting diode comprises more PN junctions. Referring to FIG. 3, the light-emitting diode further comprises a third buffer layer 60, a second tunneling junction 70, a fourth buffer layer 80, and a third light-emitting unit 90 stacked in sequence on the second light-emitting unit 50.

The second light-emitting unit 50 further comprises a fifth semiconductor layer having the first conductivity type, the third light-emitting unit 90 comprises a sixth semiconductor layer having the second conductivity type, and the second tunneling junction 70 comprises a seventh semiconductor layer having the first conductivity type and an eighth semiconductor layer having the second conductivity type.

A bandgap width of the third buffer layer 60 is between a bandgap width of the fifth semiconductor layer and a bandgap width of the seventh semiconductor layer, and a bandgap width of the fourth buffer layer 80 is between a bandgap width of the eighth semiconductor layer and a bandgap width of the sixth semiconductor layer.

Exemplarily, the fifth semiconductor layer is a second P-type AlInP confinement layer.

Exemplarily, the sixth semiconductor layer is a third N-type AlInP confinement layer. Optionally, the third light-emitting unit 90 further comprises a third active layer and a third P-type AlInP confinement layer.

Exemplarily, the third buffer layer 60 is a second hole buffer layer.

Exemplarily, the fourth buffer layer 80 is a second electron buffer layer.

Exemplarily, the seventh semiconductor layer is a second P-type AlGaAs layer; the eighth semiconductor layer is a second N-type GaAs layer.

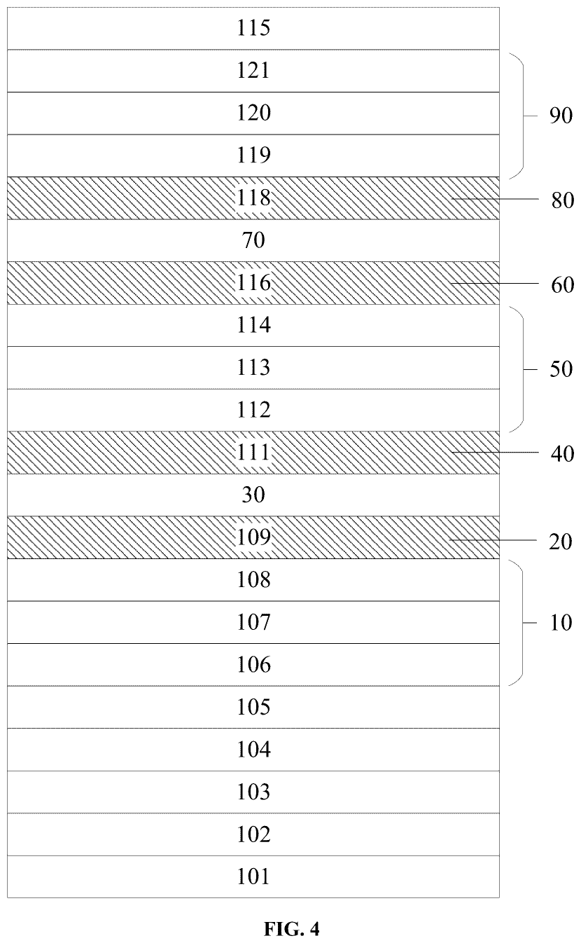

FIG. 4 is a schematic structural diagram of another light-emitting diode according to an embodiment of the disclosure. Compared with FIG. 3, the detailed structure of each film layer is further refined. Referring to FIG. 4, compared with FIG. 2, this light-emitting diode further comprises a second hole buffer layer 116, a second tunneling junction 70, a second electron buffer layer 118, a third N-type AlInP confinement layer 119, a third active layer 120, and a third P-type AlInP confinement layer 121.

The second hole buffer layer 116 is the third buffer layer 60, the second electron buffer layer 118 is the fourth buffer layer 80, and the third N-type AlInP confinement layer 119, the third active layer 120, and the third P-type AlInP confinement layer 121 constitute the third light-emitting unit 90.

The second hole buffer layer 116, the second tunneling junction 70, the second electron buffer layer 118, the third N-type AlInP confinement layer 119, the third active layer 120, and the third P-type AlInP confinement layer 121 are located between the second P-type AlInP confinement layer 114 and the P-type current spreading layer 115.

The second hole buffer layer 116, the second tunneling junction 70, the second electron buffer layer 118, the third N-type AlInP confinement layer 119, the third active layer 120, and the third P-type AlInP confinement layer 121 are stacked in sequence on the second P-type AlInP confinement layer 114.

The second tunneling junction 70 comprises a second P-type AlGaAs layer and a second N-type GaAs layer stacked in sequence. The bandgap width of the second hole buffer layer 116 is between the bandgap width of the second P-type AlInP confinement layer 114 and the bandgap width of the second P-type AlGaAs layer. The bandgap width of the second electron buffer layer 118 is between the bandgap width of the third N-type AlInP confinement layer 119 and the bandgap width of the second N-type GaAs layer.

In the embodiment of the disclosure, the second hole buffer layer 116 is a P-type doped (Al_{y}Ga_{1-y})_{0.5}In_{0.5}P layer, and y ranges from 0.15 to 1, for example, 0.5. The dopant for the P-type doped (Al_{y}Ga_{1-y})_{0.5}In_{0.5}P layer is Cp₂Mg.

The bandgap width of P-type doped (Al_{y}Ga_{1-y})_{0.5}In_{0.5}P is 2.0 to 2.1 eV, the bandgap width of the second P-type AlInP confinement layer is 2.45 eV, and the bandgap width of the second P-type AlGaAs layer is 1.4 to 1.9 eV. It can be seen that using the above material as the second hole buffer layer can ensure that the bandgap width of the second hole buffer layer is between the bandgap widths of the second P-type AlInP confinement layer and the second P-type AlGaAs layer.

In one example, the value of y gradually decreases in a direction from the second P-type AlInP confinement layer to the second tunneling junction, the maximum value of y is 1, and the minimum value of y is 0.15 to 0.3, e.g., 0.2.

In this implementation, the value of y gradually decreases in the direction from the second P-type AlInP confinement layer to the second tunneling junction, so that the bandgap width of the second hole buffer layer gradually decreases in the direction from the second P-type AlInP confinement layer to the second tunneling junction, making the energy band differences at the interfaces between the second hole buffer layer and the second P-type AlInP confinement layer and between the second hole buffer layer and the second P-type AlGaAs layer relatively small.

In other examples, the value of y may be constant or vary in other ways.

Exemplarily, a doping concentration of the second hole buffer layer is 1.5E18 to 2.5E18 cm⁻³, e.g., 2E18 cm⁻³.

Exemplarily, a thickness of the second hole buffer layer is 20 to 100 nm, e.g., 60 nm.

Exemplarily, the second P-type AlGaAs layer in the second tunneling junction 70 is a P-type AlₐGa₁₋ₐAs layer, where 0≤a≤0.3. The thickness of the second P-type AlGaAs layer is 10 to 40 nm, e.g., 25 nm. The dopant for the second P-type AlGaAs layer is CBr₄ or CCl₄. A doping concentration of the second P-type AlGaAs layer is 0.5E20 to 2E20 cm⁻³, for example, 1E20 cm⁻³.

A thickness of the second N-type GaAs layer in the second tunneling junction 70 is 10 to 40 nm, e.g., 25 nm. The dopant for the second N-type GaAs layer is Si₂H₆ or diethyl telluride. A doping concentration of the second N-type GaAs layer is 0.8E19 to 3E19 cm⁻³, for example, 2E19 cm⁻³.

In the embodiment of the disclosure, the second electron buffer layer 118 is an N-type doped (Al_{z}Ga_{1-z})_{0.5}In_{0.5}P layer, and z ranges from 0.15 to 1, e.g., 0.5. The dopant for the second electron buffer layer is Si₂H₆.

The bandgap width of the second N-type GaAs layer is 1.4 eV, and the bandgap width of the third N-type AlInP confinement layer is 2.45 eV. Using the above material as the second electron buffer layer can ensure that the bandgap width of the second electron buffer layer is between the bandgap widths of the third N-type AlInP confinement layer and the second N-type GaAs layer.

In one example, the value of z gradually increases in a direction from the second tunneling junction to the third N-type AlInP confinement layer, the maximum value of z is 1, and the minimum value of z is 0.15 to 0.3, e.g., 0.2.

In this implementation, the value of z gradually increases in the direction from the second tunneling junction to the third N-type AlInP confinement layer, so that the bandgap width of the second electron buffer layer gradually increases in the direction from the second tunneling junction to the third N-type AlInP confinement layer, making the energy band differences at the interfaces between the second electron buffer layer and the second N-type GaAs layer and between the second electron buffer layer and the third N-type AlInP confinement layer relatively small.

In other examples, the value of z may be constant or vary in other ways.

Exemplarily, a doping concentration of the second electron buffer layer is 2E18 to 3E18 cm⁻³, e.g., 2.5E18 cm⁻³.

Exemplarily, a thickness of the second electron buffer layer is 20 to 100 nm, e.g., 60 nm.

Exemplarily, a thickness of the third N-type AlInP confinement layer 119 is 200 to 300 nm, e.g., 250 nm. The dopant for the third N-type AlInP confinement layer 119 is Si₂H₆. A doping concentration of the third N-type AlInP confinement layer 119 is 1E18 to 2E18 cm⁻³, e.g., 1.5E18 cm⁻³.

Exemplarily, the third active layer 120 is a multi-quantum well layer. A thickness of a quantum well in the multi-quantum well layer is 3 to 5 nm, e.g., 4 nm; a thickness of a quantum barrier in the multi-quantum well layer is 5 to 10 nm, e.g., 8 nm. The number of periods of the multi-quantum well layer is 2 to 7, e.g., 5.

Exemplarily, a thickness of the third P-type AlInP confinement layer 121 is 200 to 300 nm, e.g., 250 nm. The dopant for the third P-type AlInP confinement layer 121 is Cp₂Mg. A doping concentration of the third P-type AlInP confinement layer 121 is 0.3E18 to 1E18 cm⁻³, e.g., 0.5E18 cm⁻³.

The light-emitting diode may further comprise more PN junctions and tunneling junctions connecting the PN junctions. The structure may refer to the design of the second hole buffer layer 116, the second tunneling junction 70, the second electron buffer layer 118, the third N-type AlInP confinement layer 119, the third active layer 120, and the third P-type AlInP confinement layer 121. That is, it comprises multiple periods of structures on the basis of FIG. 2, each period comprising the second hole buffer layer 116, the second tunneling junction 70, the second electron buffer layer 118, the third N-type AlInP confinement layer 119, the third active layer 120, and the third P-type AlInP confinement layer 121.

It is worth noting that the embodiments of the disclosure mainly provide an epitaxial structure in a light-emitting diode. In addition, the light-emitting diode may further comprise an electrode structure connected to the epitaxial structure. For example, in the example of FIG. 2, two electrodes of the electrode structure are respectively connected to the N-type GaAs ohmic contact layer 104 and the P-type current spreading layer 115, thereby providing electrical signals to the epitaxial structure to drive each light-emitting unit in the epitaxial structure to emit light. This is not described in detail in the embodiments of the disclosure.

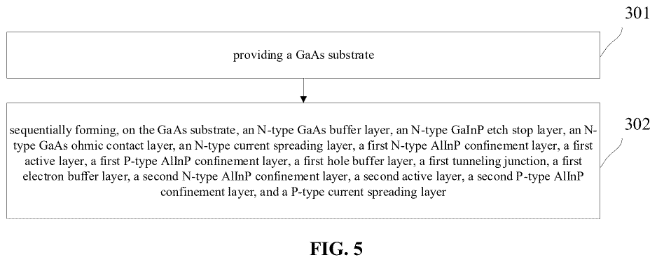

FIG. 5 is a flowchart of a method for manufacturing a light-emitting diode according to an embodiment of the disclosure. Referring to FIG. 5, the method comprises:

301. providing a GaAs substrate.

302. sequentially forming, on the GaAs substrate, an N-type GaAs buffer layer, an N-type GaInP etch stop layer, an N-type GaAs ohmic contact layer, an N-type current spreading layer, a first N-type AlInP confinement layer, a first active layer, a first P-type AlInP confinement layer, a first hole buffer layer, a first tunneling junction, a first electron buffer layer, a second N-type AlInP confinement layer, a second active layer, a second P-type AlInP confinement layer, and a P-type current spreading layer.

The first tunneling junction comprises a first P-type AlGaAs layer and a first N-type GaAs layer stacked in sequence. The bandgap width of the first hole buffer layer is between the bandgap width of the first P-type AlInP confinement layer and the bandgap width of the first P-type AlGaAs layer. The bandgap width of the first electron buffer layer is between the bandgap width of the second N-type AlInP confinement layer and the bandgap width of the first N-type GaAs layer.

In the embodiment of the disclosure, the first hole buffer layer with a moderate bandgap width is inserted between the first P-type AlInP confinement layer and the first P-type AlGaAs layer, which reduces the energy band difference at the interlayer interface, allowing electrons to tunnel well across the interface. Similarly, the first electron buffer layer with a moderate bandgap width is inserted between the second N-type AlInP confinement layer and the first N-type GaAs layer, which reduces the energy band difference at the interlayer interface, allowing electrons to tunnel well across the interface. In summary, adding the hole and electron buffer layers facilitates electron tunneling, achieving the purpose of reducing voltage and improving the luminous efficiency of the light-emitting diode.

In the embodiment of the disclosure, the first hole buffer layer is a P-type doped (Al_{y}Ga_{1-y})_{0.5}In_{0.5}P layer, and y ranges from 0.15 to 1. The dopant for the P-type doped (Al_{y}Ga_{1-y})_{0.5}In_{0.5}P layer is Cp₂Mg.

The bandgap width of P-type doped (Al_{y}Ga_{1-y})_{0.5}In_{0.5}P is 2.0 to 2.1 eV, the bandgap width of the first P-type AlInP confinement layer is 2.45 eV, and the bandgap width of the first P-type AlGaAs layer is 1.4 to 1.9 eV. It can be seen that using the above material as the first hole buffer layer can ensure that the bandgap width of the first hole buffer layer is between the bandgap widths of the first P-type AlInP confinement layer and the first P-type AlGaAs layer.

In one example, the value of y gradually decreases in a direction from the first P-type AlInP confinement layer to the first tunneling junction, the maximum value of y is 1, and the minimum value of y is 0.15 to 0.3.

In this implementation, the value of y gradually decreases in the direction from the first P-type AlInP confinement layer to the first tunneling junction, so that the bandgap width of the first hole buffer layer gradually decreases in the direction from the first P-type AlInP confinement layer to the first tunneling junction, making the energy band differences at the interfaces between the first hole buffer layer and the first P-type AlInP confinement layer and between the first hole buffer layer and the first P-type AlGaAs layer relatively small.

In other examples, the value of y may be constant or vary in other ways.

Exemplarily, a doping concentration of the first hole buffer layer is 1.5E18 to 2.5E18 cm⁻³.

Exemplarily, a thickness of the first hole buffer layer is 20 to 100 nm.

In the embodiment of the disclosure, the first electron buffer layer is an N-type doped (Al_{z}Ga_{1-z})_{0.5}In_{0.5}P layer, and z ranges from 0.15 to 1. The dopant for the first electron buffer layer is Si₂H₆.

The bandgap width of the first N-type GaAs layer is 1.4 eV, and the bandgap width of the second N-type AlInP confinement layer is 2.45 eV. Using the above material as the first electron buffer layer can ensure that the bandgap width of the first electron buffer layer is between the bandgap widths of the second N-type AlInP confinement layer and the first N-type GaAs layer.

In one example, the value of z gradually increases in a direction from the first tunneling junction to the second N-type AlInP confinement layer, the maximum value of z is 1, and the minimum value of z is 0.15 to 0.3.

In this implementation, the value of z gradually increases in the direction from the first tunneling junction to the second N-type AlInP confinement layer, so that the bandgap width of the first electron buffer layer gradually increases in the direction from the first tunneling junction to the second N-type AlInP confinement layer, making the energy band differences at the interfaces between the first electron buffer layer and the first N-type GaAs layer and between the first electron buffer layer and the second N-type AlInP confinement layer relatively small.

In other examples, the value of z may be constant or vary in other ways.

Exemplarily, a doping concentration of the first electron buffer layer is 2E18 to 3E18 cm⁻³.

Exemplarily, a thickness of the first electron buffer layer is 20 to 100 nm.

In an embodiment of the disclosure, during the growth of the hole buffer layer, the molar flow ratio (V/III ratio) of phosphine (PH₃) to the metal-organic source is controlled to be 20 to 30, the growth rate can be controlled at 0.45 to 0.55 nm/s, and the growth temperature can be 650 to 670° C. Under the condition of (Al_{y}Ga_{1-y})_{0.5}In_{0.5}P lattice matching, the flow rate of TMAl is gradually decreased, and the flow rate of TMGa is gradually increased to achieve the requirement of gradually decreasing the energy band. The phosphine can be an electronic special gas with a purity of more than 99.9999%.

During the growth of the hole buffer layer, the dopant source Cp₂Mg is introduced at an appropriate flow rate to achieve a suitable carrier concentration of 1.5E18 cm⁻³ to 2.5E18 cm⁻³.

In an embodiment of the disclosure, during the growth of the electron buffer layer, the molar flow ratio (V/III ratio) of phosphine (PH₃) to the metal-organic source is controlled to be 20 to 30, the growth rate can be controlled at 0.45 to 0.55 nm/s, and the growth temperature can be 650 to 670° C. Under the condition of (Al_{z}Ga_{1-z})_{0.5}In_{0.5}P lattice matching, the flow rate of TMAl is gradually increased, and the flow rate of TMGa is gradually decreased to achieve the requirement of gradually increasing the energy band. The phosphine can be an electronic special gas with a purity of more than 99.9999%.

During the growth of the electron buffer layer, the dopant source Si₂H₆ is introduced at an appropriate flow rate to achieve a suitable carrier concentration of 2E18 to 3E18 cm⁻³.

Optionally, the method for manufacturing the light-emitting diode further comprises: before forming the P-type current spreading layer, sequentially forming, on the second P-type AlInP confinement layer, a second hole buffer layer, a second tunneling junction, a second electron buffer layer, a third N-type AlInP confinement layer, a third active layer, and a third P-type AlInP confinement layer.

The second tunneling junction comprises a second P-type AlGaAs layer and a second N-type GaAs layer stacked in sequence; the bandgap width of the second hole buffer layer is between the bandgap width of the second P-type AlInP confinement layer and the bandgap width of the second P-type AlGaAs layer, and the bandgap width of the second electron buffer layer is between the bandgap width of the third N-type AlInP confinement layer and the bandgap width of the second N-type GaAs layer.

The above are merely embodiments of the disclosure and are not intended to limit the disclosure. Any modifications, equivalent substitutions, improvements, etc. made within the spirit and principle of the disclosure shall be included in the protection scope of the disclosure.

What is claimed is:

1. A light-emitting diode, comprising:
a first light-emitting unit, a first buffer layer, a first tunneling junction, a second buffer layer, and a second light-emitting unit stacked in sequence;
wherein
the first light-emitting unit comprises a first semiconductor layer having a first conductivity type; the second light-emitting unit comprises a second semiconductor layer having a second conductivity type; the first tunneling junction comprises a third semiconductor layer having the first conductivity type and a fourth semiconductor layer having the second conductivity type; the first conductivity type is different from the second conductivity type; and
a bandgap width of the first buffer layer is between a bandgap width of the first semiconductor layer and a bandgap width of the third semiconductor layer, and a bandgap width of the second buffer layer is between a bandgap width of the fourth semiconductor layer and a bandgap width of the second semiconductor layer.

2. The light-emitting diode according to claim 1, wherein the first semiconductor layer is a first P-type AlInP confinement layer; the first buffer layer is a first hole buffer layer; the second buffer layer is a first electron buffer layer; the second semiconductor layer is a second N-type AlInP confinement layer; the third semiconductor layer is a first P-type AlGaAs layer, and the fourth semiconductor layer is a first N-type GaAs layer.

3. The light-emitting diode according to claim 1, wherein the first buffer layer is a P-type doped (Al_{y}Ga_{1-y})_{0.5}In_{0.5}P layer, and y ranges from 0.15 to 1.

4. The light-emitting diode according to claim 3, wherein a value of y gradually decreases in a direction from the first semiconductor layer to the first tunneling junction, a maximum value of y is 1, and a minimum value of y is 0.15 to 0.3.

5. The light-emitting diode according to claim 3, wherein a doping concentration of the first buffer layer is 1.5E18 to 2.5E18 cm⁻³.

6. The light-emitting diode according to claim 1, wherein the second buffer layer is an N-type doped (Al_{z}Ga_{1-z})_{0.5}In_{0.5}P layer, and z ranges from 0.15 to 1.

7. The light-emitting diode according to claim 6, wherein a value of z gradually increases in a direction from the first tunneling junction to the second semiconductor layer, a maximum value of z is 1, and a minimum value of z is 0.15 to 0.3.

8. The light-emitting diode according to claim 6, wherein a doping concentration of the second buffer layer is 2E18 to 3E18 cm⁻³.

9. The light-emitting diode according to claim 1, wherein a thickness of the first buffer layer is 20 to 100 nm, and a thickness of the second buffer layer is 20 to 100 nm.

10. The light-emitting diode according to claim 1, further comprising:
a third buffer layer, a second tunneling junction, a fourth buffer layer, and a third light-emitting unit stacked in sequence on the second light-emitting unit;
wherein
the second light-emitting unit further comprises a fifth semiconductor layer having the first conductivity type; the third light-emitting unit comprises a sixth semiconductor layer having the second conductivity type; and the second tunneling junction comprises a seventh semiconductor layer having the first conductivity type and an eighth semiconductor layer having the second conductivity type; and
a bandgap width of the third buffer layer is between a bandgap width of the fifth semiconductor layer and a bandgap width of the seventh semiconductor layer, and a bandgap width of the fourth buffer layer is between a bandgap width of the eighth semiconductor layer and a bandgap width of the sixth semiconductor layer.
